(19) United States
(12) Patent Application Publication
(10) Pub. No.: US 2008/0278258 A1
(43) Pub. Date: Nov. 13, 2008

(54) INTEGRATED CIRCUIT HAVING RE-CONFIGURABLE BALUN CIRCUIT AND METHOD THEREFOR

(76) Inventor: Lianjun Liu, Chandler, AZ (US)

Correspondence Address: FREESCALE SEMICONDUCTOR, INC.;LAW DEPARTMENT, 7700 WEST PARMER LANE MD:TX32/PL02, AUSTIN, TX, 78729, US

(21) Appl. No.: 11/745,486

(22) Filed: May 8, 2007

(51) Int. Cl. H03H 7/42

(52) U.S. Cl. 333/25

(57) ABSTRACT

A balun circuit comprises a balun transformer having first and second windings, and first and second variable capacitors. The first variable capacitor has a first plate electrode coupled to the first terminal of the first winding, and a second plate electrode coupled to the second terminal of the first winding. The second variable capacitor has a first plate electrode coupled to the first terminal of the second winding, and a second plate electrode coupled to the second terminal of the second winding. The first variable capacitor is tunable between first and second capacitance values. The second variable capacitor is tunable between third and fourth capacitance values. Tuning the variable capacitors allows the balun circuit to be re-configurable to operate in both the first frequency band and the second frequency band.

### BACKGROUND

1. Field

This disclosure relates generally to integrated circuits, and more specifically, to an integrated circuit having a re-configurable balun circuit and method therefor.

2. Related Art

Balanced/unbalanced (balun) transformers are used in radio receivers to convert a single-ended (unbalanced) signal from an antenna to a differential (balanced) signal; and are used in radio transmitters to convert a differential signal to a single-ended signal. In the past, balun transformers were discrete devices mounted on printed circuit boards. Today, IPD (integrated passive device) balun transformers are typically formed on the same semiconductor substrate as a radio frequency (RF) front-end circuit. Many RF transceivers, such as used in cellular handsets, are designed to operate in several frequency bands and use separate signal paths for each band in both the transmitter portion and the receiver portion. Each signal path requires its own balun transformer tailored for a specific center frequency and bandwidth. Using a separate IPD balun transformer for each signal path increases the size and the number of components of an RF front-end circuit and results in increased manufacturing costs.

Therefore, a need exists for a way to solve the above problems.

### BRIEF DESCRIPTION OF THE DRAWINGS

The present invention is illustrated by way of example and is not limited by the accompanying figures, in which like references indicate similar elements. Elements in the figures are illustrated for simplicity and clarity and have not necessarily been drawn to scale.

FIG. 1 illustrates a schematic diagram of a re-configurable balun circuit for use in a receiver in accordance with one embodiment.

FIG. 2 illustrates a schematic diagram of a re-configurable balun circuit for use in a transmitter in accordance with another embodiment.

FIG. 3 illustrates a block diagram of a multiple band radio circuit having the re-configurable balun circuits of FIG. 1 and FIG. 2.

### DETAILED DESCRIPTION

One aspect of the illustrated embodiment includes a circuit comprising: a balun transformer having first and second windings, the first winding having first and second terminals and the second winding having first and second terminals; a first variable capacitor having a first plate electrode coupled to the first terminal of the first winding, and a second plate electrode coupled to the second terminal of first winding, the first variable capacitor being tunable between first and second capacitance values, the first capacitance value for allowing the circuit to operate in a first frequency band and the second capacitance value for allowing the circuit to operate in a second frequency band, wherein the first frequency band is different from the second frequency band; and a second variable capacitor having a first plate electrode coupled to the first terminal of the second winding, and a second plate electrode coupled to the second terminal of the second winding, the second variable capacitor being tunable between third and fourth capacitance values, the third capacitance value for allowing the circuit to operate in the first frequency band and a fourth capacitance value for allowing the circuit to operate in the second frequency band.

Another aspect of the illustrated embodiment includes An integrated circuit comprising: an integrated passive device (IPD) balun transformer having first and second windings, the first winding having first and second terminals and the second winding having first and second terminals; a first capacitor coupled between the first and second terminals of the first winding; a first variable capacitor coupled in parallel with the first capacitor, the first variable capacitor being tunable between first and second capacitance values; a second capacitor coupled between the first and second terminals of the second winding; and a second variable capacitor coupled in parallel with the second capacitor, the second variable capacitor being tunable between third and fourth capacitance values.

A method for operating a multi-band balun circuit, the method comprising: providing a balun transformer having first and second windings; coupling a first variable capacitor between first and second terminals of the first winding; coupling a second variable capacitor between first and second terminals of the second winding; providing a mode signal to cause the multi-band balun circuit to operate in a first frequency band; tuning the first variable capacitor to provide a first capacitance value and tuning the second variable capacitor to provide a second capacitance value in response to the mode signal; providing the mode signal to cause the multi-band balun circuit to operate in a second frequency band different from the first frequency band; and tuning the first variable capacitor to provide a third capacitance value different from the first capacitance value and tuning the second variable capacitor to provide a fourth capacitance valve different from the second capacitance value.

FIG. 1 illustrates a schematic diagram of a re-configurable balun circuit 10 for use in a receiver in accordance with one embodiment. Re-configurable balun circuit 10 includes balun transformer 12, fixed value capacitors 14 and 16, and variable capacitors 18 and 20. Balun transformer 12 is formed having a first, primary, winding 13 and a second, secondary, winding 15. The windings 13 and 15 of balun transformer 12 are not directly coupled together. and depend on flux coupling to operate. In the illustrated embodiment, balun transformer 12 is characterized as being a conventional integrated passive device (IPD) transformer implemented on an integrated circuit. Capacitor 14 has a first plate electrode coupled to a first terminal of primary winding 13, and a second plate electrode coupled to a second terminal of primary winding 13. Variable capacitor 18 has a first plate electrode coupled to the first terminal of primary winding 13, and a second plate electrode coupled to the second terminal of primary winding 13. The first terminal of primary winding 13 and the first plate electrodes of capacitors 14 and 18 receive a single-ended input signal labeled “IN RX”. The second terminal of primary winding 13 and the second plate electrodes of capacitors 14 and 18 are coupled to a ground terminal. In the illustrated embodiment, the ground terminal may be coupled to an analog ground. Variable capacitors 18 and 20 are implemented as conventional micro-electro mechanical system (MEMS) type variable capacitors. In the illustrated embodiment, variable capacitors 18 and 20 are implemented on the same integrated circuit as the balun transformer 12. Variable capacitor 18 is tuned between one of two capacitance values in response to a control signal labeled “RX BAND”. Variable capacitor 20 is tuned between one of two capacitance values in response to control signal “RX BAND”. Note that in other embodiments, the variable capacitors 18 and 20 may receive different control signals.

Capacitor 16 has a first plate electrode coupled to a first terminal of secondary winding 15, and a second plate electrode coupled to a second terminal of secondary winding 15. Variable capacitor 20 has a first plate electrode coupled to a first terminal of secondary winding 15, and a second plate electrode coupled to a second terminal of secondary winding 15. The first terminal of secondary winding 15 and the first plate electrodes of capacitors 16 and 20 provide an output signal labeled “OUT RX +”. The second terminal of secondary winding 15 and the second plate electrodes of capacitors 16 and 20 provide an output signal labeled “OUT RX−”. The signals OUT RX+ and OUT RX− are characterized as being differential signals.

Balun circuit 10 is re-configurable to operate in a first frequency band or a second frequency band different from the first frequency band by changing the capacitance values provided by variable capacitors 18 and 20. In one embodiment, the low frequency band is between 824 mega Hertz (MHz) and 915 MHz, and the high frequency band is from 1710 MHz to 1910 MHz for the GSM cellular standard. In other embodiments, the frequency bands may be different. For example, the 3G and WCDMA cellular standards extend the above frequency bands to 824 MHz to 960 MHz for the low frequency band and 1710 MHz to 2170 MHz for the high frequency band. Also, in another embodiment, a portion of the low and high frequency bands may overlap. Balun circuit 10 is especially useful in a multi-band radio receiver, such as for example, a front-end circuit of a multi-band cellular telephone handset. Because balun circuit 10 is re-configurable to operate in two frequency bands, balun circuit 10 eliminates the need to have a separate balun circuit for each of the high and low frequency bands of a multi-band radio. This saves costs and reduces a size of a front-end receiver circuit.

A resonant frequency w is defined by an equation ω=1/\sqrt{LC}, where L is inductance and C is capacitance. A conventional balun transformer designed to operate in one frequency band has a particular primary self inductance and size optimized for the particular frequency band. For example, an IPD transformer designed to operate in a high frequency band of 1710 to 1910 MHz may have a winding of two turns with a certain geometry. Likewise, an IPD transformer designed to operate in a relatively lower frequency band of 824 to 915 MHz may have a winding of four turns with a certain geometry because the high frequency band has a center frequency that is approximately twice the center frequency of the low frequency band. To design balun circuit 10 to operate in both the high and low frequency bands, the transformer may be chosen to have a self inductance (and the size and winding) between the high and low band transformers described above. To determine the capacitance values of capacitors 14, 16, 18, and 20, the primary and secondary sides of transformer 12 are considered separately. In the above resonant frequency equation for ω for the primary side, the parallel combination of capacitors 14 and 18 are C and the inductance of primary winding 13 is L. For a given L, for example, the inductance of primary winding 13, the capacitance value C is determined around a particular resonant frequency, for example, the center frequency of the high frequency band 824 to 915 MHz. The capacitance value C is calculated for both the low and high frequency bands for both the primary and secondary windings of transformer 12. When calculating the capacitance values for secondary winding 15, L is the inductance of secondary winding 15. In the illustrated embodiment, a portion of the capacitance values C for the primary winding 13 for both the high and low frequency bands is provided by fixed capacitor 14, and a portion of capacitance values C for the secondary winding 15 for both the high and low frequency bands is provided by fixed capacitor 16. The balance of capacitance C is provided by the variable capacitors 18 and 20. The variable capacitor 18 is designed to have a first capacitance value for the low frequency band and a second capacitance value for the high capacitance band so that the total capacitance for the parallel combination of capacitors 14 and 18 provides the correct capacitance for both high and low frequency bands for primary winding 13. Also, variable capacitor 20 is designed to have a third capacitance value for the low frequency band and a fourth capacitance value for the high capacitance band so that the total capacitance for the parallel combination of capacitors 16 and 20 provides the correct capacitance for both high and low frequency bands for secondary winding 15. Using fixed capacitors in parallel with the variable capacitors reduces the amount of capacitance that is provided by the variable capacitors. In one embodiment, the variable capacitors provide zero capacitance for one frequency band and a calculated capacitance value for the other frequency band. In another embodiment, only the variable capacitors 18 and 20 are used to provide all of the calculated capacitance values for both bands so that the fixed capacitors 14 and 16 are not used.

The variable capacitors 18 and 20 are implemented as conventional MEMS variable capacitors having one plate electrode fixed in position with the other plate electrode being movable. The movable plate electrode is moved relative to the fixed plate electrode in response to a control signal to vary a gap between the plate electrodes. When the plate electrodes are farther apart, the capacitance is lower, and when the plate electrodes are moved closer together, the capacitance increases.

During operation, when the control signal RX BAND is in a first logic state, or first voltage, variable capacitors 18 and 20 provide their first respective capacitance values so that balun circuit 10 operates in a first frequency band. When the control signal RX BAND is a second logic state, or second voltage, variable capacitors 18 and 20 provide their second respective capacitance values so that balun circuit 10 operates in a second frequency band that is different from the first frequency band.

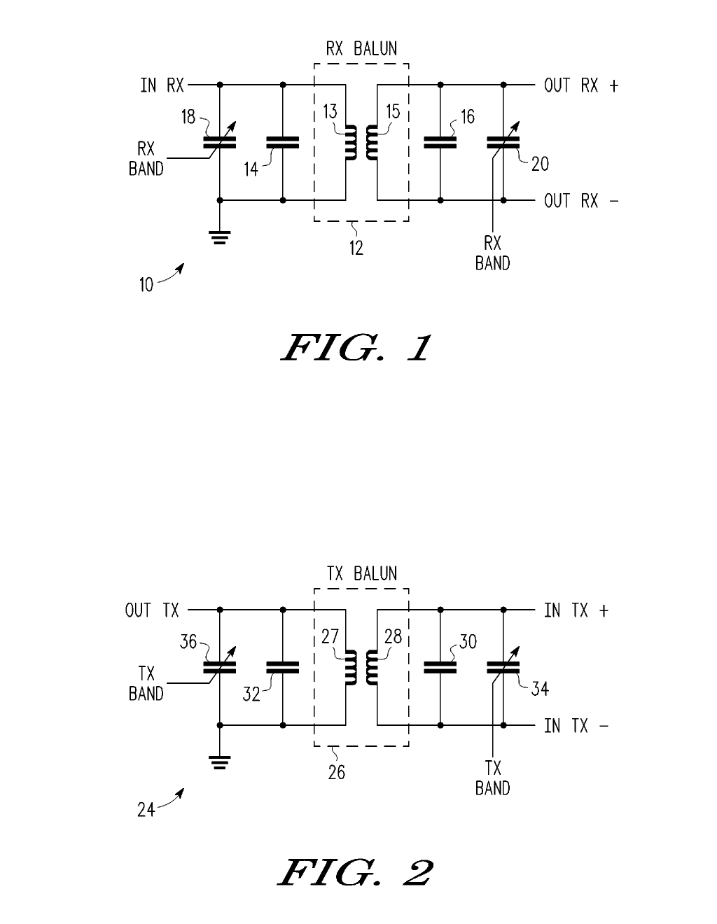

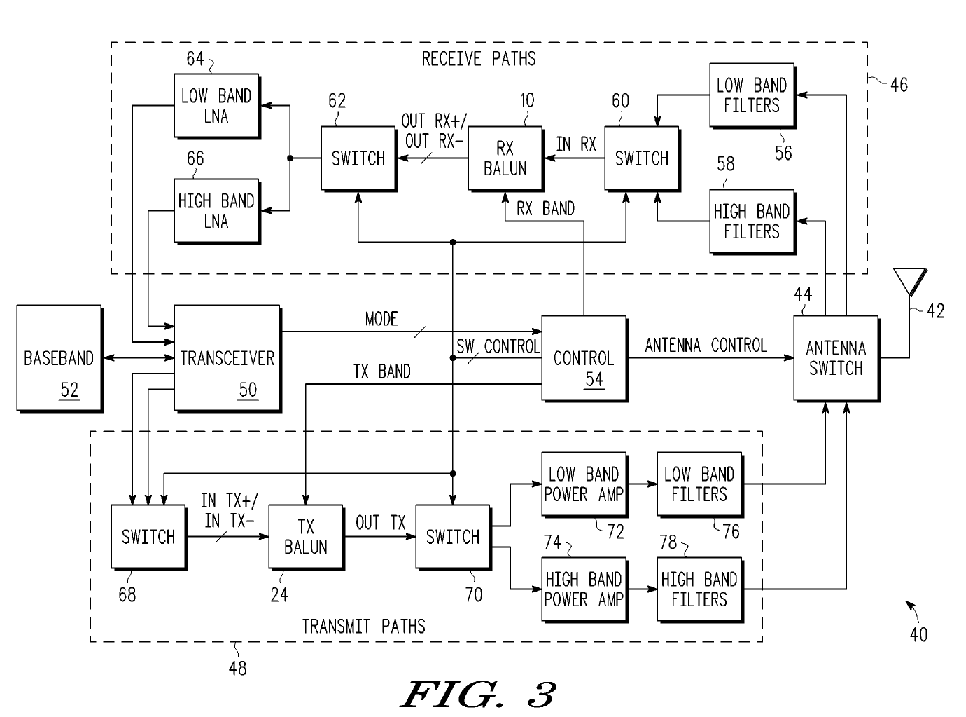

FIG. 2 illustrates a schematic diagram of a re-configurable balun circuit 24 for use in a transmitter in accordance with another embodiment. Re-configurable balun circuit 24 includes balun transformer 26, fixed value capacitors 30 and 32, and variable capacitors 34 and 36. Balun transformer 26 is formed having a first, primary, winding 28 and a second, secondary, winding 27. Balun circuit 24 is essentially the same as balun circuit 10 except that balun circuit 24 is designed to operate in a transmit path of a multi-band radio. Therefore, balun circuit 24 receives differential input signals labeled “IN TX+” and “IN TX−” and provides a single-ended output signal labeled “OUT TX”. Also, the variable capacitors 34 and 36 are conventional MEMS variable capacitors, are implemented on the same integrated circuit as balun transformer 26, and are responsive to a control signal labeled “TX BAND”. In addition, the capacitance values for each of capacitors 30, 32, 34, and 36 are determined the same as for balun circuit 10.

FIG. 3 illustrates a block diagram of a multiple band radio circuit 40 having the re-configurable balun circuits of FIG. 1 and FIG. 2. Radio circuit 40 includes antenna 42, antenna switch 44, receive paths 46, transmit paths 48, transceiver 50, control circuit 54, and baseband circuit 52. Receive paths 46 includes low band filters 56, high band filters 58, switches 60 and 62, balun circuit 10 (see FIG. 1), low band low noise amplifier (LNA) 64, and LNA 66. Transmit paths 48 includes switches 68 and 70, balun circuit 24 (see FIG. 2), low band power amplifier 72, high band power amplifier 74, low band filters 76, and high band filters 78. A “front-end” portion of radio 40 includes antenna 42, antenna switch 44, receive paths 46, and transmit paths 48.

Antenna 42 is coupled to antenna switch 44. Antenna switch 44 couples antenna 42 to one of low band filters 56 or high band filters 58 of receive paths 46, or to one of low band filters 76 or high band filters 78 of transmit paths 48 in response to a control signal labeled “ANTENNA CONTROL” from control circuit 54. Control circuit 54 receives various control signals from transceiver 50 including one or more mode controls labeled “MODE”. Control signals MODE determines whether radio 40 is transmitting or receiving and whether radio 40 operating in a first frequency band or a second frequency band. In response to control signals MODE, control circuit 54 provides control signal ANTENNA CONTROL to antenna switch 44 to couple antenna 42 to the appropriate path. Also, control circuit 54 provides control signals labeled “SW CONTROL to control switches 60 and 62 to couple balun circuit 10 into the receive paths 46 if the radio 40 is in receive mode, or to control switches 68 and 70 to couple balun circuit 24 into the transmit paths 48 if radio 40 is in transmit mode. In addition, control circuit 54 provides control signal RX BAND to control balun circuit 10 as described above in the discussion of FIG. 1, and provides control signal TX BAND to control balun circuit 24 as described above in the discussion of FIG. 2. Control circuit 54 may be implemented separately as illustrated in FIG. 3, or may be implemented as part of transceiver 50 or baseband circuit 52.

Radio 40 receives and transmits radio frequency (RF) signals in either of a low frequency band and a high frequency band. As an example, assume radio 40 is in receive mode in the low frequency band. A single-ended RF signal is received at antenna 42 and routed to low band filters 56 by antenna switch 44. Low band filters 56 includes one or more conventional filter circuits to filter noise from the RF signal. Control circuit 54 causes switch 60 to couple balun circuit 10 to low band filters 56. Balun circuit 10 receives the single-ended signal IN RX and provides differential signals OUT RX+/OUT RX− to switch 62. Control signal RX BAND causes balun 10 to provide the correct capacitance value for the low frequency band signal. Switch 62 couples the output balun circuit 10 to inputs of low band LNA 64. Low band LNA 64 then provides amplified differential signals to inputs of transceiver 50. Transceiver 50 provides the signals to baseband circuit 52 for additional processing.

As another example, assume radio 40 is in transmit mode in the high frequency band. A differential signal to be transmitted is provided by baseband circuit 53 to transceiver 50 and corresponding differential signals are provided to switch 68. Switch 68 couples the outputs of transceiver 50 to differential inputs IN TX+/IN TX− of balun circuit 24 in response to signal SW CONTROL. Control signal TX BAND causes balun circuit 24 to re-configure balun circuit 24 to provide the correct capacitance values for high frequency band operation as discussed above regarding FIG. 2. A single-ended output signal OUT TX is provided by balun circuit 24 to switch 70. In response to signal SW CONTROL, switch 70 provides the single-ended output signal OUT TX to high band power amplifier 74 and high band filters 78. Antenna switch 44 routes the signal to be transmitted to antenna 42.

Using a single re-configurable balun circuit in the signal path of a multi-band radio instead of one balun circuit for each frequency band reduces the number of balun circuits in a the front-end circuit of a radio, thus reducing size and cost of the radio.

Note that in other embodiments of radio 40, more than one antenna may be used. Also, in other embodiments LNAs 64 and 66 may be combined into one wideband LNA. Likewise, amplifiers 72 and 74 may be combined. Note that if LNA 64 and 66 are combined and amplifiers 72 and 74 are combined, switches 62 and 70 are not needed. In addition, switch 68 could be removed or integrated in the transceiver chip 50.

By now it should be appreciated that there has been provided a re-configurable balun circuit for use in a multi-band radio that uses variable capacitors to tune the balun circuit between first and second frequency bands, thus eliminating the need for separate balun circuits for each frequency band.

Thus, it is to be understood that the architectures depicted herein are merely exemplary, and that in fact many other architectures can be implemented which achieve the same functionality. In an abstract, but still definite sense, any arrangement of components to achieve the same functionality is effectively “associated” such that the desired functionality is achieved. Hence, any two components herein combined to achieve a particular functionality can be seen as “associated with” each other such that the desired functionality is achieved, irrespective of architectures or intermedial components. Likewise, any two components so associated can also be viewed as being “operably connected,” or “operably coupled,” to each other to achieve the desired functionality.

Moreover, the terms “front,” “back,” “top,” “bottom,” “over,” “under” and the like in the description and in the claims, if any, are used for descriptive purposes and not necessarily for describing permanent relative positions. It is understood that the terms so used are interchangeable under appropriate circumstances such that the embodiments of the invention described herein are, for example, capable of operation in other orientations than those illustrated or otherwise described herein.

Although the invention is described herein with reference to specific embodiments, various modifications and changes can be made without departing from the scope of the present invention as set forth in the claims below. Accordingly, the specification and figures are to be regarded in an illustrative rather than a restrictive sense, and all such modifications are intended to be included within the scope of the present invention. Any benefits, advantages, or solutions to problems that are described herein with regard to specific embodiments are not intended to be construed as a critical, required, or essential feature or element of any or all the claims.

Furthermore, the terms “a” or “an,” as used herein, are defined as one or more than one. Also, the use of introductory phrases such as “at least one” and “one or more” in the claims should not be construed to imply that the introduction of another claim element by the indefinite articles “a” or “an” limits any particular claim containing such introduced claim element to inventions containing only one such element, even when the same claim includes the introductory phrases “one or more” or “at least one” and indefinite articles such as “a” or “an.” The same holds true for the use of definite articles.

Unless stated otherwise, terms such as “first” and “second” are used to arbitrarily distinguish between the elements such terms describe. Thus, these terms are not necessarily intended to indicate temporal or other prioritization of such elements.

The term “coupled,” as used herein, is not intended to be limited to a direct coupling or a mechanical coupling.

What is claimed is:

1. A circuit comprising:
a balun transformer having first and second windings, the first winding having first and second terminals and the second winding having first and second terminals;
a first variable capacitor having a first plate electrode coupled to the first terminal of the first winding, and a second plate electrode coupled to the second terminal of first winding, the first variable capacitor being tunable between first and second capacitance values, the first capacitance value for allowing the circuit to operate in a first frequency band and the second capacitance value for allowing the circuit to operate in a second frequency band, wherein the first frequency band is different from the second frequency band; and
a second variable capacitor having a first plate electrode coupled to the first terminal of the second winding, and a second plate electrode coupled to the second terminal of the second winding, the second variable capacitor being tunable between third and fourth capacitance values, the third capacitance value for allowing the circuit to operate in the first frequency band and a fourth capacitance value for allowing the circuit to operate in the second frequency band.

2. The circuit of claim 1, wherein the first and second variable capacitors are characterized as being micro-electro mechanical system (MEMS) variable capacitors responsive to a control signal.

3. The circuit of claim 1, wherein the balun transformer and the first and second variable capacitors are implemented on an integrated circuit.

4. The circuit of claim 1, wherein the first terminal of the first winding is coupled to receive a single-ended input signal having a frequency within one of the first or second frequency bands, the second terminal of the first winding is coupled to a ground terminal, and wherein the first and second terminals of the second winding function as differential output terminals.

5. The circuit of claim 4, wherein the circuit is implemented in a receive path of a multi-band radio frequency front-end circuit.

6. The circuit of claim 1, wherein the first and second terminals of the first winding function as differential input terminals, the first terminal of the second winding is coupled to provide a single-ended output signal, and the second terminal of the second winding is coupled to a ground terminal.

7. The circuit of claim 6, wherein the circuit is implemented in a transmit path of a multi-band radio frequency front-end circuit.

8. The circuit of claim 1, wherein the balun transformer is an integrated passive device (IPD) type transformer.

9. The circuit of claim 1, wherein the first frequency band includes 824 mega Hertz (MHz) to 915 MHz, and the second frequency band includes 1710 MHz to 1910 MHz.

10. An integrated circuit comprising:
an integrated passive device (IPD) balun transformer having first and second windings, the first winding having first and second terminals and the second winding having first and second terminals;
a first capacitor coupled between the first and second terminals of the first winding;
a first variable capacitor coupled in parallel with the first capacitor, the first variable capacitor being tunable between first and second capacitance values;
a second capacitor coupled between the first and second terminals of the second winding; and
a second variable capacitor coupled in parallel with the second capacitor, the second variable capacitor being tunable between third and fourth capacitance values.

11. The integrated circuit of claim 10, wherein during a first mode of operation the integrated circuit operates in a first frequency band and during a second mode of operation the integrated circuit operates in a second frequency band different from the first frequency band, wherein during the first mode of operation the first variable capacitor is tuned to provide the first capacitance value and the second variable capacitor is tuned to provide the third capacitance value, and wherein during the second mode of operation the first variable capacitor is tuned to provide the second capacitance value and the second variable capacitor is tuned to provide the fourth capacitance value.

12. The integrated circuit of claim 10, wherein the circuit is implemented in a receive path of a multi-band radio frequency front-end circuit, and wherein the first terminal of the first winding is coupled to receive a single-ended input signal having a frequency within one of the first or second frequency bands, the second terminal of the first winding is coupled to a ground terminal, and the first and second terminals of the second winding function as differential output terminals.

13. The integrated circuit of claim 10, wherein the circuit is implemented in a transmit path of a multi-band radio frequency front-end circuit, and wherein the first and second terminals of the first winding function as differential input terminals, the first terminal of the second winding is coupled to provide a single-ended output signal, and the second terminal of the second winding is coupled to a ground terminal.

14. The integrated circuit of claim 10, wherein the first frequency band includes 824 MHz to 915 MHz, and the second frequency band includes 1710 MHz to 1910 MHz.

15. The integrated circuit of claim 10, wherein the first and second variable capacitors are characterized as being micro-electro mechanical system (MEMS) variable capacitors responsive to a control signal.

16. A method for operating a multi-band balun circuit, the method comprising:
providing a balun transformer having first and second windings;
coupling a first variable capacitor between first and second terminals of the first winding;
coupling a second variable capacitor between first and second terminals of the second winding;
providing a mode signal to cause the multi-band balun circuit to operate in a first frequency band;
tuning both the first variable capacitor to provide a first capacitance value and tuning the second variable capacitor to provide a second capacitance value in response to the mode signal;
providing the mode signal to cause the multi-band balun circuit to operate in a second frequency band different from the first frequency band; and
tuning the first variable capacitor to provide a third capacitance value different from the first capacitance value and tuning the second variable capacitor to provide a fourth capacitance valve different from the second capacitance value.

17. The method of claim 16, wherein providing the balun transformer further comprises providing an integrated passive device (IPD) balun transformer.

18. The method of claim 16, further comprising:
coupling a first fixed value capacitor to the first and second terminals of the first winding; and
coupling a second fixed value capacitor to the first and second terminals of the second winding.

19. The method of claim 16, wherein coupling the first variable capacitor further comprises providing the first variable capacitor as a micro-electro mechanical system (MEMS) variable capacitor, and coupling the second variable capacitor further comprises providing the second variable capacitor as a MEMS variable capacitor.

20. The method of claim 16, further comprising:
providing a single-ended signal at the first terminal of the first winding;
coupling the second terminal of the first winding to ground; and
providing differential signals at the first and second terminals of the second winding.
